(19) United States
(12) Patent Application Publication
(10) Pub. No.: US 2007/0148879 A1
(43) Pub. Date: Jun. 28, 2007

(54) III-V compound semiconductor heterostructure MOSFET with a high workfunction metal gate electrode and process of making the same

(76) Inventors: Matthias Passlack, Chandler, AZ (US); Ravindranath Droopad, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/315,732

(22) Filed: Dec. 22, 2005

(51) Int. Cl. H01L 21/336

(52) U.S. Cl. 438/285

(57) ABSTRACT

A method of forming a metal-insulator-compound semiconductor structure comprises providing an insulator layer overlying a compound semiconductor substrate, the insulator layer having a surface, and forming a metal layer on the surface of the insulator layer using metal organic chemical vapor deposition.

### CROSS-REFERENCE TO CO-PENDING APPLICATIONS

This application is related to co-pending patent applications, Ser. No. 10/882,482, entitled “Method of Passivating Oxide/Compound Semiconductor Interface,” filed Jun. 30, 2004 (Attorney Docket Number SC13349ZP); Ser. No. 11/236,186, entitled “Process of Making A III-V Compound Semiconductor Heterostructure MOSFET,” filed Sep. 27, 2005 (Attorney Docket SC13350ZP), Ser. No. 11/236,185, entitled “A III-V Compound Semiconductor Heterostructure MOSFET Device,” filed Sep. 27, 2005 (Attorney Docket SC13350ZP PF), Ser. No. 11/236,187, entitled “Charge Compensated Dielectric Layer Structure and Method of Making the Same,” filed Sep. 27, 2005 (Attorney Docket SC13784ZP), and Ser. No. 11/239,749, entitled “Method of Forming an Oxide Layer on a Compound Semiconductor Structure,” filed Sep. 30, 2005 (Attorney Docket SC 11692ZP PD 1), all assigned to the assignee of the present disclosures and incorporated herein by reference.

### BACKGROUND

The present disclosures relate to semiconductor structures, and more particularly, to a process and structure of a III-V compound semiconductor heterostructure MOSFET having a high workfunction metal gate electrode.

III-V compound semiconductor process technology has utilized various techniques in the fabrication of compound semiconductor heterostructure MOSFETs which present a number of problems. For example, prior known techniques such as e-beam evaporation and sputtering processes damage the MOS structure due to ions, charged particles, x-rays, etc. Prior fabrication techniques also do not allow for an in-situ oxide surface passivation step prior to gate metal deposition. Furthermore, prior fabrication techniques produce gate metals, such as platinum (Pt), which are incompatible with efficient oxide surface bonding, which adversely limits an available workfunction. Moreover, methods such as sputtering or e-beam deposition limits a range of available workfunction to less than or equal to 5.4 eV and causes damage to the MOS structure.

Implant-free GaAs based enhancement mode MOSFET technology requires high workfunction materials for NMOSFETs. Platinum (Pt) has a workfunction of 5.6 eV. While platinum (Pt) represents a good choice, it is very difficult to etch. This limits gate electrode patterning to lift-off processes which are not as easily scalable as subtractive processes which use etching. It is therefore desirable to provide a high workfunction gate metal which is easy to etch and which has a selective etch chemistry regarding the gate oxide surface (e.g., either Ga₂O₃ of GdₓGa_{0.4-x}O_{0.6} or other).

Accordingly, there is a need for an improved method and apparatus for overcoming the problems in the art.

### BRIEF DESCRIPTION OF THE DRAWINGS

The present invention is illustrated by way of example and not limited by the accompanying figures, in which like references indicate similar elements, and in which:

FIG. 1 is a cross-sectional view of a semiconductor structure during the manufacture thereof according to one embodiment of the present disclosure;

FIG. 2 is a cross-sectional view of the semiconductor structure including source/drain ohmic contacts and a high work function gate metal electrode according to one embodiment of the present disclosure;

FIG. 3 is schematic representation view of a MOCVD chamber utilized in fabricating a portion of the semiconductor structure according to one embodiment of the present disclosure; and

FIG. 4 is a flow chart view of a method for forming the semiconductor structure according to one embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

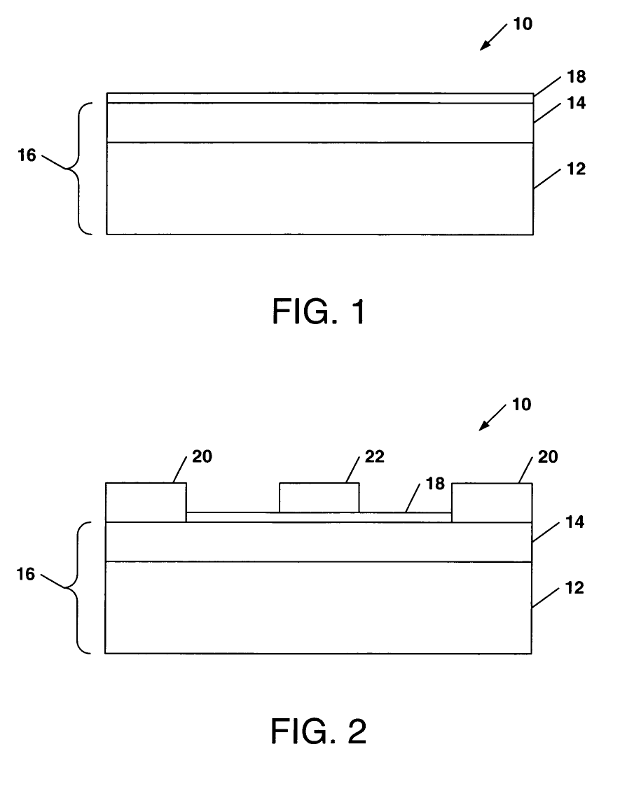

FIG. 1 is a cross-sectional view of a semiconductor structure 10 that includes a substrate 12 and an epitaxial layer 14, which together represent a III-V compound semiconductor substrate 16. Semiconductor structure 10 further includes a gate insulator layer 18. The III-V compound semiconductor substrate 16 and gate insulator layer 18 are for use with a method according to one embodiment of the present disclosure. Substrate 12 comprises any material suitable for a III-V semiconductor device structure. The epitaxial layer 14 comprises any epitaxial layer or stack of layers suitable for a III-V semiconductor device structure. Note that while only one epitaxial layer 14 is illustrated for simplicity, the epitaxial layer 14 can comprise a stack of one or more epitaxial layers. Gate insulator layer 18 comprises any dielectric layer or stack of dielectric layers suitable for a III-V semiconductor device structure.

In one embodiment, substrate 12 comprises a III-V compound semiconductor substrate with one or more layers 14 of III-V material epitaxially formed on an upper surface thereof (not shown). For purposes of this disclosure, the substrate and any epitaxial layers formed thereon will be referred to simply as a compound semiconductor substrate. For example, substrate 12 can comprise a III-V material such as GaAs or InP and epitaxial layer(s) 14 can comprise, for example, any suitable layer structure of In, Ga, P, As, Sb, or Al containing compounds.

In one embodiment, gate insulator layer 18 comprises a deposited gate oxide that has been deposited to a desired target thickness with use of a suitable oxide deposition system. The gate oxide is preferably deposited to the desired thickness, as opposed to being deposited beyond the target thickness and then etched back to the desired thickness. In one embodiment, the as-grown GaAs based MOSFET structure comprises a GdGaO dielectric stack deposited onto GaAs based epitaxial layers. The target sheet resistivity is 400-500 Ohm/sq.

In one embodiment, an optional protective layer (not shown) may be used, wherein the protective layer is deposited onto the semiconductor structure 10 after removal from the oxide deposition system used for depositing the gate oxide 18. It is desirable to minimize the amount of time that the gate oxide is exposed to ambient after removal of the semiconductor structure from the oxide deposition system and prior to application of the protective layer. In one embodiment, aluminum nitride (AlN) is used as the protective layer. A protective layer of AIN is compatible with the gate oxide, i.e. AlN can be deposited and removed without damage to the gate oxide and the underlying oxide-semiconductor interface. The protective layer protects a surface of the gate oxide layer from undesirable contaminants and surface modifications. In other words, the protective layer functions to minimize surface gettering of contaminants during storage. The protective layer also provides for prevention of impurity diffusion into the oxide and towards the underlying oxide-semiconductor interface during temperature exposure.

During device processing, the optional protective layer (not shown) would remain in place in regions that correspond to future active areas. Suitable hardmasks for use during isolation trench formation (not shown) include JVD SiN, SiO, and sputtered AlN. In addition, suitable processing equipment is selected for handling various processing requirements. The optional protective layer and its use can comprise, for example, a protective layer as disclosed in co-pending patent application, Ser. No. 11/236,185, entitled “A III-V Compound Semiconductor Heterostructure MOSFET Device,” filed Sep. 27, 2005, and will not be discussed further herein.

FIG. 2 is a cross-sectional view of the semiconductor structure 10 that further includes source/drain ohmic contacts 20 and a gate electrode 22, according to one embodiment of the present disclosure. The formation of the source/drain ohmic contacts 20 includes forming the ohmic contacts to be coupled to the compound semiconductor substrate (e.g., substrate 12 and epitaxial layer(s) 14) proximate opposite sides of an active region defined within the compound semiconductor substrate. There may exist an overlap (not shown) between the ohmic contact metal and the gate oxide 18. The overlap prevents the creation of depleted access regions, and thus prevents device failure. Depleted access regions occur when an ohmic contact is laterally separated from an edge of the gate oxide, and wherein a surface portion of the epitaxial layer 14 is exposed. In other words, the overlap prevents formation of a gap between the gate oxide covered surface and the metal contact.

Formation of ohmic contacts 20 can include use of suitable metal schemes for GaAs. In addition, formation of ohmic contacts 20 includes using a suitable rapid thermal anneal (RTA) subsequent to a deposit and patterning of a desired ohmic contact material. Hardmasks used during formation of the ohmic contacts 20 can include JVD SiN, SiO, sputtered AlN. In one embodiment, contact metal 20 comprises a palladium/gold (Pd/Au) alloy. In another embodiment, contact metal 20 comprises one or more layers of (i) Ni, (ii) Ge, (iii) Au, or (iv) alloys thereof for GaAs.

FIG. 2 further includes a gate contact 22 according to one embodiment of the present disclosure. Formation of gate contact 22 comprises the sequence described herein below. If an optional protective layer is used, then the protective layer that is in direct contact with the gate oxide 18 is first removed in the immediate gate region without damaging the gate oxide layer 18. The exposed region could then be subjected to a suitable post-deposition anneal (PDA), if not previously performed for the entire active device area.

Next, a gate metal is deposited using metal organic chemical vapor deposition (MOCVD). In particular, the gate metallization includes an MOCVD high work function material, such as a metallic sulfide or metallic selenide for positive threshold voltages (Vₜₕ). The high work function metal gate is used for enhancement mode operation. In one embodiment, the gate metal layer is selected from the group consisting of TiS₂, VS₂, NbSe₂, VSe₂, TiSe₂, NiSe₂, and CoSe₂.

In one embodiment, the gate metal is deposited in-situ after gate oxide growth and patterned by a subtractive process at an appropriate time in the process flow. One group of gate metal materials according to an embodiment of the present disclosure includes selenides. At the 2005 MRS Spring Meeting, Darmstadt University of Technology, Darmstadt, Germany, in a presentation “Interfaces in CdTe Solar Cells: From Idealized Concepts To Technology,” Jaegermann et al. disclosed the vacuum workfunction of NbSe₂ to be 5.88 eV. This vacuum workfunction is 0.28 V higher than that of Pt (5.6 eV). The applicants of the present disclosure recognize that with a melting point of greater than 1300° C., NbSe₂ is compatible with thermal requirements of III-V MOSFET manufacturing. In addition, Jaegermann et al. manufactured the metals of VS₂ and TiS₂ as thin films and determined the same to have a workfunction of 5.7 eV. Furthermore, Jaegermann et al. manufactured the metals NbSe₂ and VSe₂ as bulk material and determined the same to have a workfunction of 5.9 eV and 5.7 eV, respectively. Moreover, the applicants of the present disclosure recognized the use of MOCVD for high workfunction gate metals and that the MOCVD process can be applied to III-V compound semiconductor MOSFET technology, as disclosed herein.

The device 10 can further include a step gate or field plate. Power devices need extra measures to increase a breakdown voltage. Since the density of interface states (Dᵢₜ) is low, a T-gate may already serve as step gate when a proper distance between the upper bar of the T and the device surface is realized.

According to one embodiment, the workfunction of the gate contact 22 is selected to be greater than 5.6 eV, according to the desired device type. For implant-free MOSFETs, a high workfunction is desired. The gate metal contact electrode can comprise a gate metal layer selected from the group consisting of TiS₂, VS₂, NbSe₂, VSe₂, TiSe₂, NiSe₂, and CoSe₂, the gate metal layer having a workfunction on the order of greater than 5.6 eV.

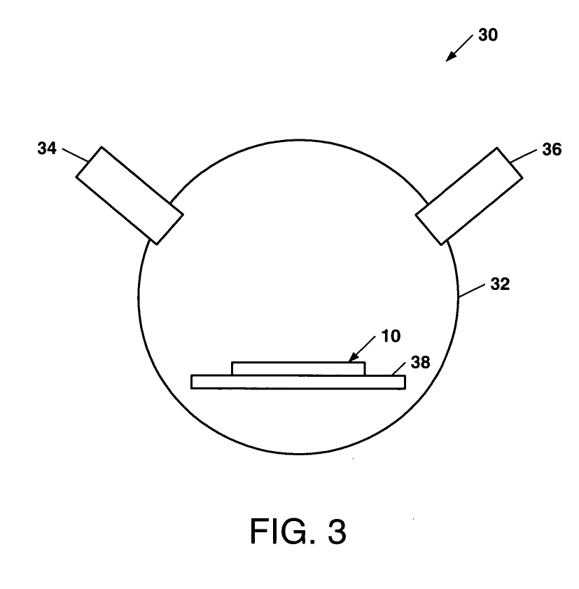

FIG. 3 is schematic representation view of a MOCVD system 30 having a chamber 32 utilized in fabricating a portion of the semiconductor structure 10 according to one embodiment of the present disclosure. MOCVD system 30 includes first and second sources (bubblers) 34 and 36 for providing prescribed precursors during fabrication of the gate metal according to the embodiments of the present disclosure. In addition, MOCVD system 30 includes a platen 38 for supporting the semiconductor structure 10 during processing, wherein the platen can be heated as appropriate for a given gate metal deposition step.

Briefly, during fabrication of gate metal, the method includes loading a III-V MOSFET wafer into the MOCVD reactor 32 and placed upon the platen 38. Following the loading of the III-V MOSFET wafer into the MOCVD chamber 32, the method optionally includes performing an in-situ surface treatment or cleaning using reactor compatible gas/precursor. The method further includes flowing precursors over the wafer surface, via first and second sublimation cells 34 and 36, respectively, and depositing gate metal.

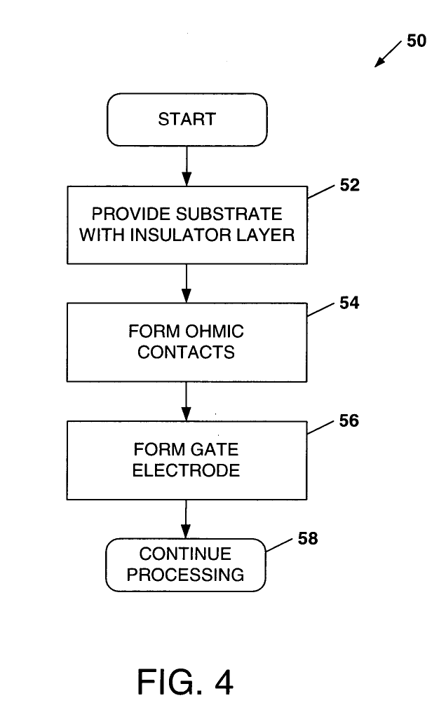

FIG. 4 is a flow chart view 50 of a method for forming the semiconductor structure 10 according to one embodiment of the present disclosure. In step 52, a III-V substrate having an insulator layer, as discussed herein, is provided. Ohmic contacts are formed, using suitable process steps, at step 54. The method further includes forming the gate electrode, at step 56, further as discussed herein. The semiconductor device 10 can be processed further according to the requirements of the particular semiconductor device application, at step 58. For example, further processing of semiconductor device 10 may include plating, via formation, metal2, etc. using suitable GaAs processing steps.

According to one embodiment of the present disclosure, a method of making a III-V compound semiconductor device includes using one or more of (i) a GdGaO/Ga2O3 dielectric stack used in the FET flow, (ii) a protective layer (specifically AlN) for oxide and oxide/semiconductor interface protection and interface passivation retention, (iii) ohmic contacts overlapping oxide to prevent depletion of channel, (iv) high workfunction gate to allow enhancement mode operation. Advantages and benefits provided by the embodiments of the present disclosure include, but are not necessarily limited to, one or more of the following: (i) for RF applications, higher performance, e.g. higher Iₘₐₓ, smaller die size, more flexible circuit designs, better linearity, lower noise, higher integration levels; (ii) combination of MOS advantages (ruggedness, scalability, integration) with advantages of III-Vs (higher efficiency, better frequency performance); or (iii) for digital, it will introduce a successful Si MOS concept of 2-D scaling into the III-V world.

According to one embodiment of the present disclosure, a compound semiconductor heterostructure MOSFET process flow includes use of a GdGaO/Ga₂O₃ dielectric stack as a gate oxide overlying a GaAs epitaxial layer. The process flow further includes using a gate oxide cap layer, device isolation implants, ohmic contacts, post deposition annealing before gate contact metal deposition, and gate contact metal deposition, as discussed further herein. The gate oxide cap layer can include an ex-situ or in-situ deposited gate oxide cap layer. The gate oxide cap layer (i) protects an underlying gate oxide surface from contamination and hydrogen load during deposition of oxides and nitrides (e.g. CVD of oxides and nitrides), (ii) substantially improves the thermal stability of hydrogen or deuterium passivation of the Ga₂O₃/GaAs interface, (ii) allows building of nitride/oxide layer structures during processing steps, and (iii) has a substantially one-hundred percent (100%) etch selectivity. In one embodiment, the gate oxide cap layer comprises a nitride such as AlN. The device isolation implants are formed in direct contact with the GdGaO/Ga₂O₃ gate dielectric stack. The ohmic contacts are formed in direct contact with the GdGaO/Ga₂O₃ gate dielectric stack. Post deposition annealing is performed before gate contact metal deposition. In addition, gate contact metal deposition occurs after forming a suitable opening in the protective layer.

According to one embodiment of the present disclosure, a method of forming a metal-insulator-compound semiconductor structure includes: providing an insulator layer overlying a compound semiconductor substrate, the insulator layer having a surface; and forming a metal layer on the surface of the insulator layer using metal organic chemical vapor deposition. The insulator layer can comprise a gate oxide layer, for example, GdGaO. The metal layer can comprise one of metallic sulfide or metallic selenide, for example, a metal layer selected from the group consisting of TiS₂, VS₂, NbSe₂, VSe₂, TiSe₂, NiSe₂, and CoSe₂. In addition, the compound semiconductor substrate can comprise a III-V substrate with one or more epitaxial layers thereon. The one or more epitaxial layers can comprise any suitable layer structure of one or more of In, Ga, P, As, Sb, or Al containing compounds.

According to another embodiment of the present disclosure, a method of forming a compound semiconductor device includes forming a gate insulator layer overlying a compound semiconductor substrate; forming ohmic contacts to the compound semiconductor substrate proximate opposite sides of an active device region defined within the compound semiconductor substrate; and forming a gate metal contact electrode on the gate insulator layer in a region between the ohmic contacts using metal organic chemical vapor deposition. In one embodiment, the gate metal contact electrode comprises one of metallic sulfide or metallic selenide. The gate metal contact electrode can be selected from the group consisting of TiS₂, VS₂, NbSe₂, VSe₂, TiSe₂, NiSe₂, and CoSe₂. In addition, the compound semiconductor substrate can comprise a III-V substrate with one or more epitaxial layers thereon. The one or more epitaxial layers can comprise any suitable layer structure of one or more of In, Ga, P, As, Sb, or Al containing compounds.

According to yet another embodiment of the present disclosure, a metal-insulator-semiconductor structure comprises an insulator layer overlying a semiconductor substrate, the insulator layer having a surface, and a metal layer comprising one of metallic sulfide or metallic selenide positioned on the surface of the insulator layer. The semiconductor substrate can comprise, for example, a compound semiconductor substrate. The compound semiconductor substrate can comprise a III-V substrate with one or more epitaxial layers thereon. In one embodiment, the insulator layer comprises a gate oxide layer, wherein the gate oxide layer comprises GdGaO. The metal layer can comprise a metal layer formed by at least one of metal organic chemical vapor deposition, sputter deposition, or laser ablation. In another embodiment, the metal layer comprises one selected from the group consisting of TiS₂, VS₂, NbSe₂, VSe₂, TiSe₂, NiSe₂, and CoSe₂. In addition, the metal-insulator-semiconductor structure can be incorporated into an integrated circuit device.

The embodiments disclosed herein are applicable across all III-V semiconductors, and as such, capture a broad concept. The embodiments are applicable to analog, digital, and mixed signal circuitry. In other words, compound semiconductor heterostructure MOSFET devices formed according to the embodiments of the method of the present disclosure can be used in a variety of RF and mixed signal semiconductor circuits. RF and mixed signal semiconductor circuits can include, for example, mobile, wireless products such as handsets, wireless local area networks (WLAN), and digital heterointegration type applications.

In the foregoing specification, the disclosure has been described in reference to the various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. For example, the present embodiments can apply to semiconductor device technologies where a high workfunction material is used as a gate electrode. The present embodiments can further apply to implant-free MOSFETs, wherein the present embodiments improve implant-free MOSFET technology in terms of stability, reliability, and scalability.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of forming a metal-insulator-compound semiconductor structure comprising:
providing an insulator layer overlying a compound semiconductor substrate, the insulator layer having a surface; and
forming a metal layer on the surface of the insulator layer using metal organic chemical vapor deposition.

2. The method of claim 1, wherein the insulator layer comprises a gate oxide layer.

3. The method of claim 2, wherein the gate oxide layer comprises GdGaO.

4. The method of claim 1, wherein the metal layer comprises one of metallic sulfide or metallic selenide.

5. The method of claim 4, wherein the metal layer is selected from the group consisting of TiS₂, VS₂, NbSe₂, VSe₂, TiSe₂, NiSe₂, and CoSe₂.

6. The method of claim 1, wherein the compound semiconductor substrate comprises a III-V substrate with one or more epitaxial layers thereon.

7. The method of claim 6, further wherein the one or more epitaxial layers comprise any suitable layer structure of one or more of In, Ga, P, As, Sb, or Al containing compounds.

8. A method of forming a compound semiconductor device comprising:
forming a gate insulator layer overlying a compound semiconductor substrate;
forming ohmic contacts to the compound semiconductor substrate proximate opposite sides of an active device region defined within the compound semiconductor substrate; and
forming a gate metal contact electrode on the gate insulator layer in a region between the ohmic contacts using metalorganic chemical vapor deposition.

9. The method of claim 8, wherein the gate metal contact electrode comprises one of metallic sulfide or metallic selenide.

10. The method of claim 9, wherein the gate metal contact electrode is selected from the group consisting of TiS₂, VS₂, NbSe₂, VSe₂, TiSe₂, NiSe₂, and CoSe₂.

11. The method of claim 8, wherein the compound semiconductor substrate comprises a III-V substrate with one or more epitaxial layers thereon.

12. The method of claim 11, further wherein the one or more epitaxial layers comprise any suitable layer structure of one or more of In, Ga, P, As, Sb, or Al containing compounds.

13. A metal-insulator-semiconductor structure comprising:
an insulator layer overlying a semiconductor substrate, the insulator layer having a surface; and
a metal layer comprising one of metallic sulfide or metallic selenide positioned on the surface of the insulator layer.

14. The metal-insulator-semiconductor structure of claim 13, wherein the semiconductor substrate comprises a compound semiconductor substrate.

15. The metal-insulator-semiconductor structure of claim 14, wherein the compound semiconductor substrate comprises a III-V substrate with one or more epitaxial layers thereon.

16. The metal-insulator-semiconductor structure of claim 13, wherein the insulator layer comprises a gate oxide layer.

17. The metal-insulator-semiconductor structure of claim 16, wherein the gate oxide layer comprises GdGaO.

18. The metal-insulator-semiconductor structure of claim 13, wherein the metal layer comprises a metal layer formed by at least one of metal organic chemical vapor deposition, sputter deposition, or laser ablation.

19. The metal-insulator-semiconductor structure of claim 13, wherein the metal layer comprise one selected from the group consisting of TiS₂, VS₂, NbSe₂, VSe₂, TiSe₂, NiSe₂, and CoSe₂.

20. The metal-insulator-semiconductor structure of claim 13, wherein the metal-insulator-semiconductor structure is incorporated into an integrated circuit device.
